(19) United States
(12) Patent Application Publication
(10) Pub. No.: US 2024/0395953 A1
(43) Pub. Date: Nov. 28, 2024

(54) FRONT SURFACE ANTI-REFLECTION COATING FOR SOLAR CELLS

(71) Applicant: Maxeon Solar Pte. Ltd., Singapore (SG)

(72) Inventor: Roderick Marstell, San Jose (CA)

(21) Appl. No.: 18/204,918

(22) Filed: Jun. 1, 2023

Related U.S. Application Data
(63) Continuation of application No. 18/202,483, filed on May 26, 2023.

(51) Int. Cl. H01L 31/0216

(52) U.S. Cl. CPC H01L 31/02168

(57) ABSTRACT

A solar cell is disclosed. The solar cell includes a substrate and an anti-reflection coating on the substrate. The anti-reflection coating includes a coating layer on the substrate that includes SiNₓ, a high refractive index coating layer that includes TiO₂ on the coating layer that includes SiNₓ, and a coating layer on the coating layer that includes TiO₂.

### CROSS-REFERENCE TO RELATED APPLICATION

This application is a continuation of U.S. patent application Ser. No. 18/202,483, filed May 26, 2023, which is incorporated by reference herein in its entirety.

### TECHNICAL FIELD

Embodiments of the disclosure pertain to anti-reflection coatings for solar cells and, in particular to an improved front surface anti-reflection coating for solar cells.

### BACKGROUND

In solar cells, the reflection of incident photons by its silicon surface is a significant source of optical losses during photovoltaic conversion. Optical losses consist of light which has the potential to generate an electron-hole pair, but doesn't, because it is reflected from the front surface of the solar cell or is not absorbed by the solar cell. Optical losses affect the power that is generated by a solar cell by lowering its current output. For the most common types of semiconductor solar cells, the entire visible spectrum of light has enough energy to create electron-hole pairs and therefore all visible light could ideally be absorbed by such solar cells. However, because the materials used on the frontside of the solar cells may not be able to absorb all such light, light is reflected, that if not reflected, could be absorbed to produce more current such that higher efficiency photovoltaic conversion could be attained. An anti-reflection coating (ARC) is a type of optical coating that is applied to the surface of photovoltaic cells to reduce reflection and to increase light absorption for purposes of improving photovoltaic conversion. Different materials have been investigated for use as anti-reflection coatings for solar cell surfaces. However, conventional anti-reflection coatings have proven less than ideal in their effectiveness.

### BRIEF DESCRIPTION OF THE DRAWINGS

FIG. 1A illustrates an exemplary operating environment for a solar cell with improved anti-reflection coating according to one embodiment.

FIG. 1B shows a front surface anti-reflection coating configuration for a solar cell according to one embodiment.

FIG. 1C shows a front surface anti-reflection coating configuration for a solar cell according to one embodiment.

FIG. 1D shows a front surface anti-reflection coating configuration for a solar cell according to one embodiment.

FIG. 1E shows a front surface anti-reflection coating configuration for a solar cell according to one embodiment.

FIG. 1F shows a front surface anti-reflection coating configuration for a solar cell according to one embodiment.

FIG. 1G shows a front surface anti-reflection coating configuration for a solar cell according to one embodiment.

FIG. 1H shows a front surface anti-reflection coating configuration for a solar cell according to one embodiment.

FIG. 1I shows a front surface anti-reflection coating configuration for a solar cell according to one embodiment.

FIG. 1J shows a front surface anti-reflection coating configuration for a solar cell according to one embodiment.

FIG. 1K illustrates the operation of a solar cell with improved anti-reflection coating according to one embodiment.

FIG. 2A shows a flowchart of a method of forming a solar cell with improved anti-reflection coating according to one embodiment.

FIG. 2B shows a flowchart of a method of forming an anti-reflection coating on a substrate according to one embodiment.

FIG. 2C shows a flowchart of a method of forming an anti-reflection coating on a substrate according to one embodiment.

FIG. 2D shows a flowchart of a method of forming an anti-reflection coating on a substrate according to one embodiment.

FIG. 2E shows a flowchart of a method of forming an anti-reflection coating on a substrate according to one embodiment.

FIG. 2F shows a flowchart of a method of forming an anti-reflection coating on a substrate according to one embodiment.

FIG. 2G shows a flowchart of a method of forming an anti-reflection coating on a substrate according to one embodiment.

### DESCRIPTION OF THE EMBODIMENTS

A solar cell with improved anti-reflection coating is described. It should be appreciated that although embodiments are described herein with reference to example solar cells with improved anti-reflection coating, the disclosure is more generally applicable to solar cells with anti-reflection coating as well as to other types of solar cells with improved anti-reflection coating. In the following description, numerous specific details are set forth in order to provide a thorough understanding of embodiments of the present disclosure. It will be apparent to one skilled in the art that embodiments of the present disclosure may be practiced without these specific details. In other instances, well-known features are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

As used herein the term “high refractive index coating layer” is intended to refer to a material layer of the herein described anti-reflection coating that has an index of refraction or refractive index of at least 2.3 at λ=633 nm.

In solar cells, the reflection of incident photons by its silicon surface is a major source of optical losses during photovoltaic conversion. Optical losses consist of light which has the potential to generate an electron-hole pair, but doesn't, because it is reflected from the front surface of the solar cell or is not absorbed by the solar cell. Optical losses affect the power that is generated by a solar cell by lowering its short-circuit current. For the most common types of semiconductor solar cells, the entire visible spectrum of light has enough energy to create electron-hole pairs and therefore all visible light could ideally be absorbed by such solar cells. However, because the materials used on the frontside of the solar cells may not transmit all such light due to the optical quality of the arrangement, light is reflected, that if not reflected, could be absorbed to produce more current such that higher photovoltaic conversion efficiency could be attained.

An anti-reflection coating (ARC) is a type of optical coating that is applied to the surface of photovoltaic cells to reduce reflection and to increase light absorption for purposes of improving photovoltaic conversion. Different materials have been investigated for use as anti-reflection coatings for solar cell surfaces. However, conventional anti-reflection coatings have proven less than ideal in their effectiveness.

Approaches that overcome the challenges of the previous approaches are disclosed herein. As part of one embodiment, a solar cell with improved front surface anti-reflection coating is disclosed. The solar cell includes a substrate and an anti-reflection coating on the substrate. The anti-reflection coating includes a coating layer on the substrate that includes SiNₓ, a high refractive index coating layer that includes TiO₂ on the coating layer that includes SiNₓ, and a coating layer on the coating layer that includes TiO₂.

In one embodiment, the anti-reflection coating is organized to include multiple layers that have different indexes of refraction that minimize reflection losses. The minimization of reflection losses is enhanced by the presence of the high refractive index coating layer that includes TiO₂. This results in a generation of electron-hole pairs that otherwise would not be generated, from the additional light, that is not reflected from the front surface, or that is absorbed in the solar cell. In one embodiment, the reduction in optical losses increases the efficiency of the solar cell such that more power can be supplied to loads.

Solar Cell with Improved Anti-Reflection Coating

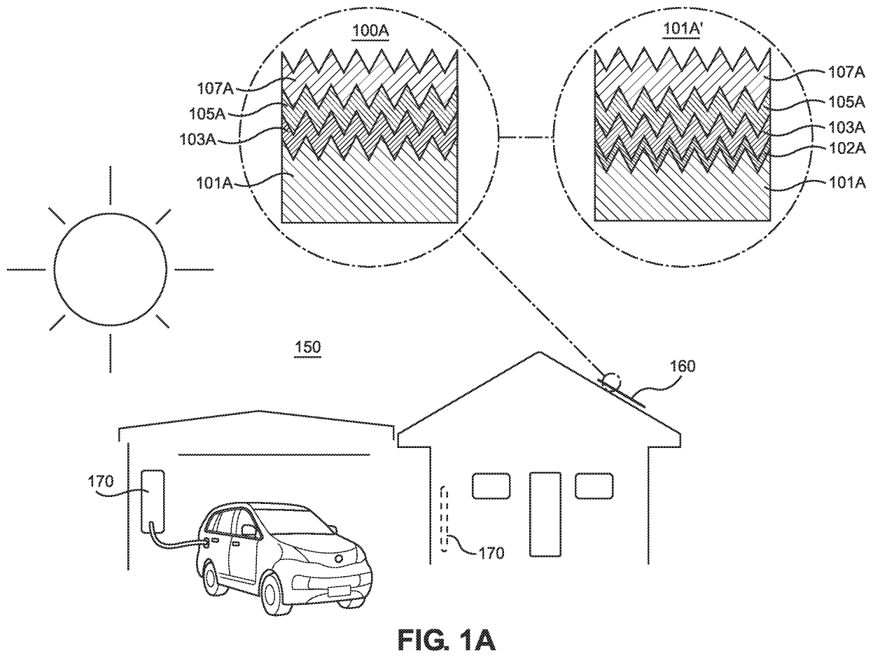

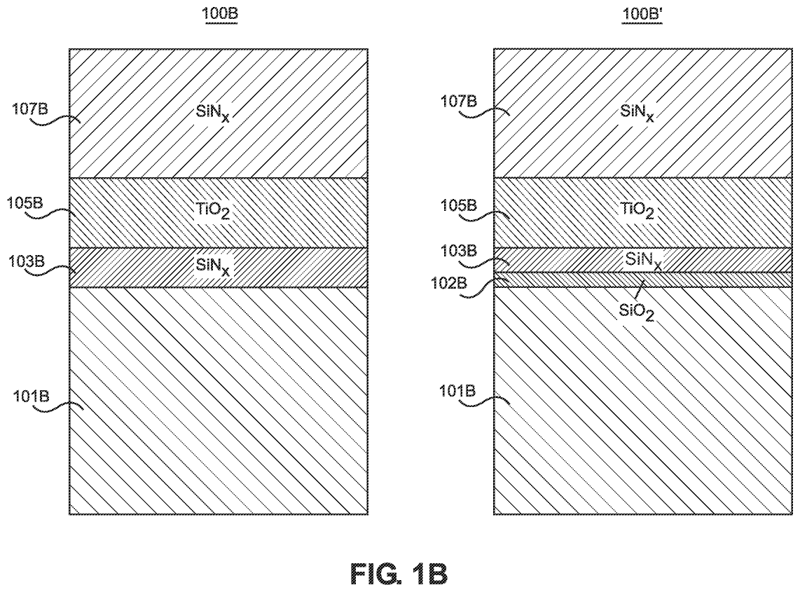

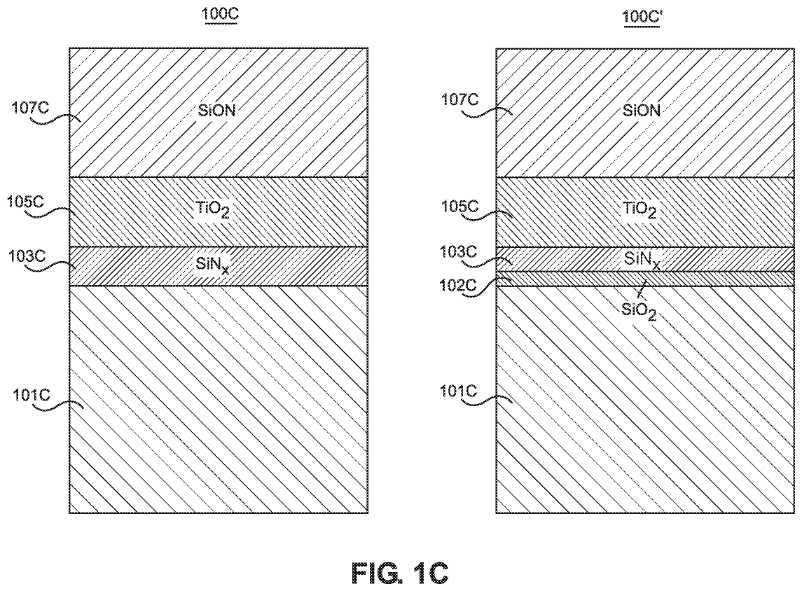

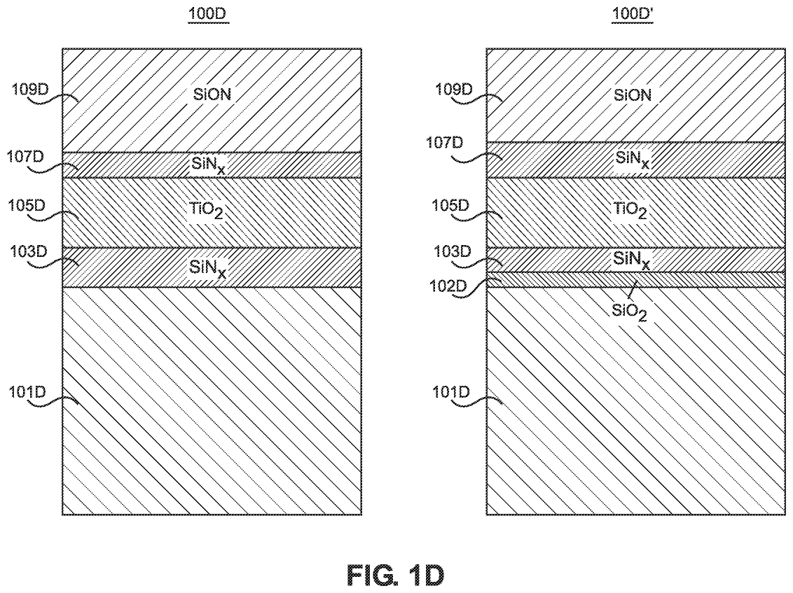

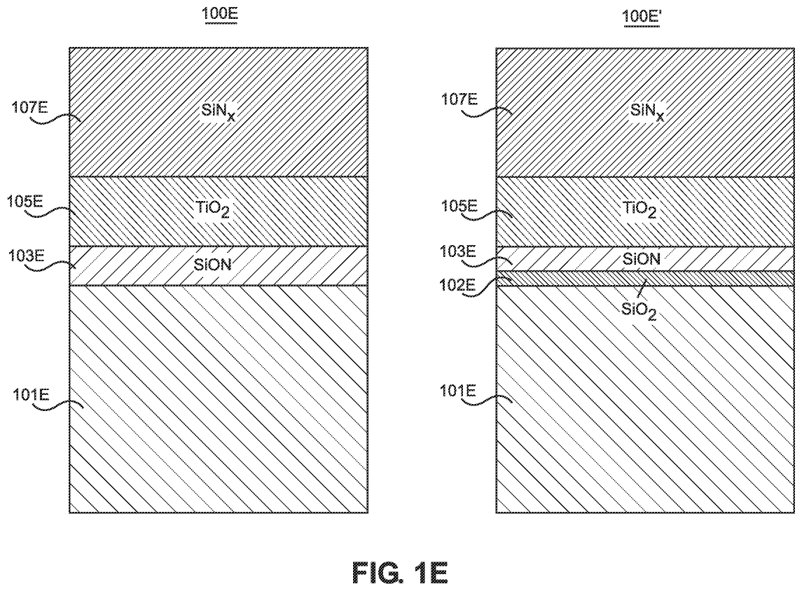

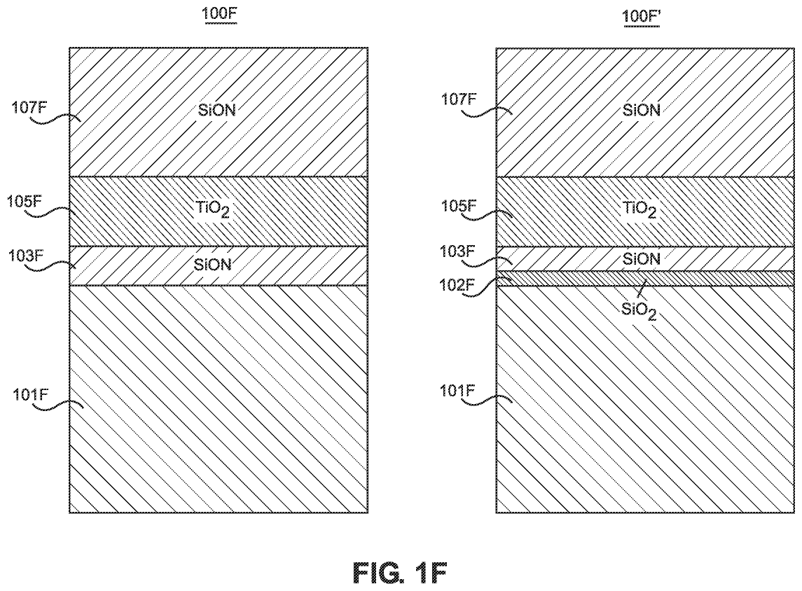

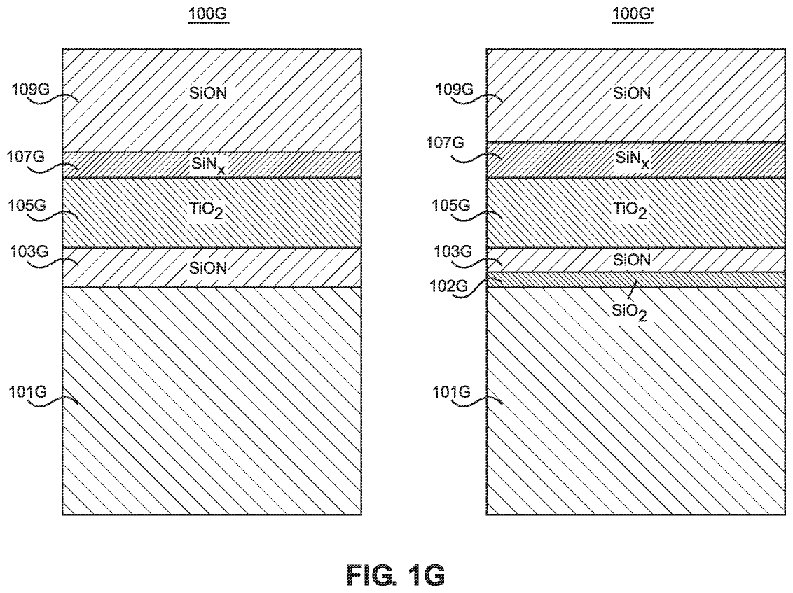

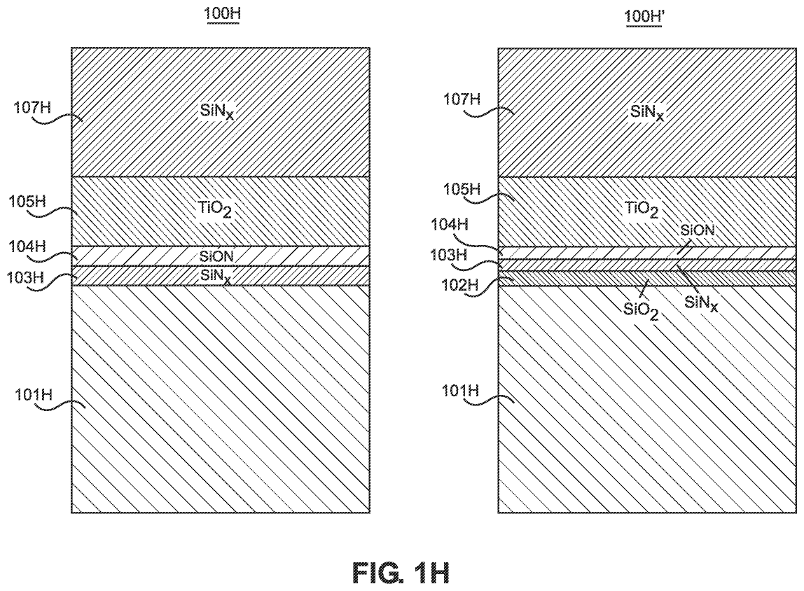

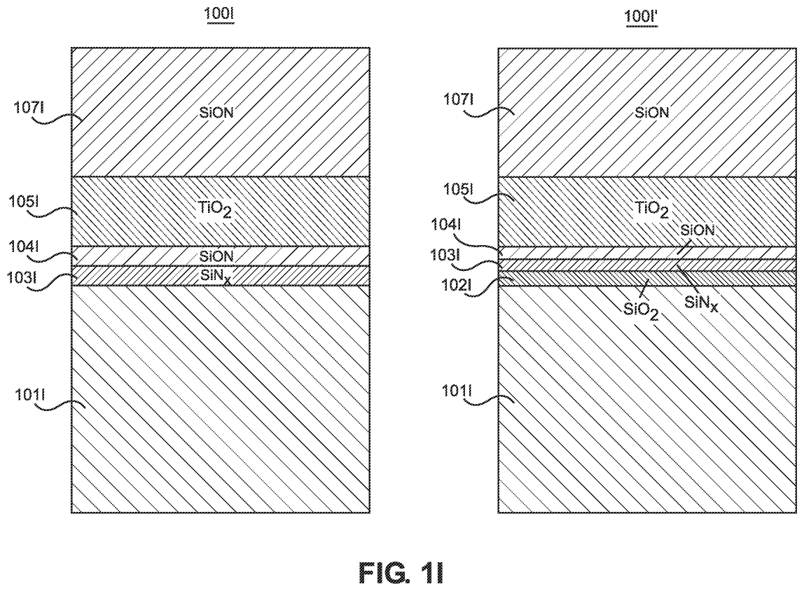

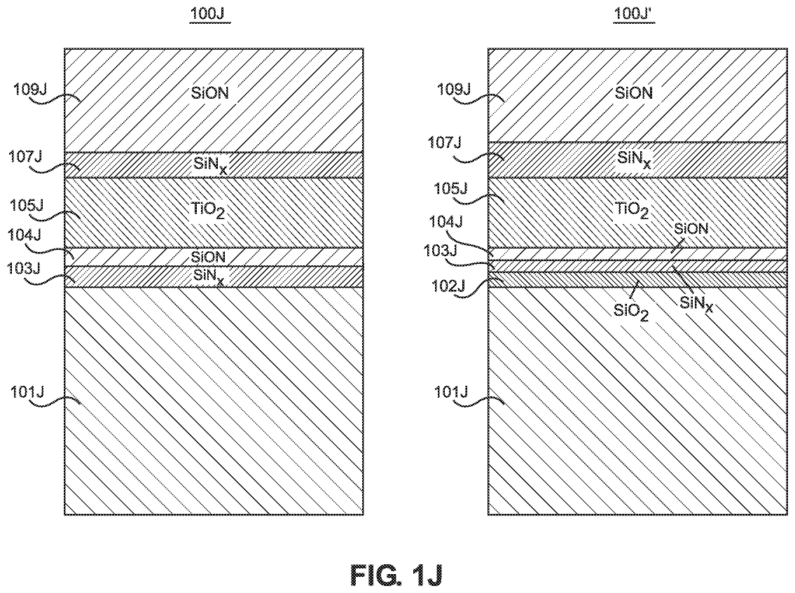

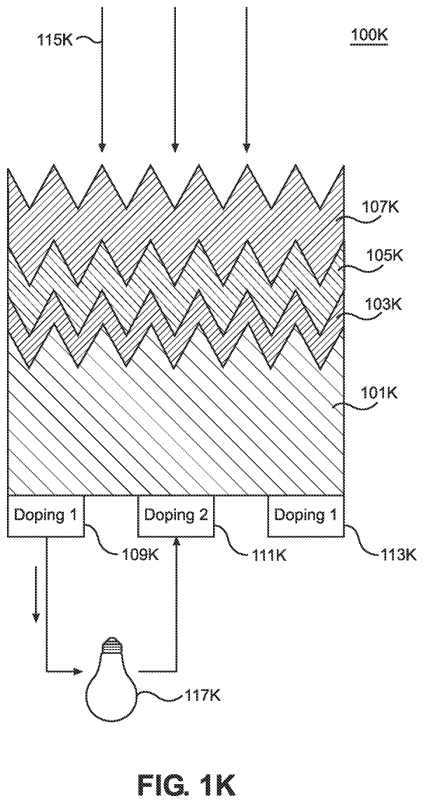

FIG. 1A illustrates an exemplary operating environment of a solar cell with improved anti-reflection coating according to one embodiment. FIG. 1A shows a location 150 that includes photovoltaic modules 160 that include solar cells 100A (hereinafter “the solar cells” or “a solar cell” or “the solar cell”) with an improved anti-reflection coating. In one embodiment, the photovoltaic modules 160 utilize the electrical energy generated by the solar cells 100A to supply the location with electricity (e.g., to power appliances 170).

FIG. 1A shows a cross-section of a portion of a solar cell 100A with improved anti-reflection coating according to one embodiment. In one embodiment, the solar cell 100A includes a wafer 101A that is covered by an anti-reflection coating that includes coating layer 103A, high refractive index coating layer 105A, and coating layer 107A.

In another embodiment, as also shown in FIG. 1A, a solar cell 100A′ is provided which has an architecture similar to that of the solar cell 100A, that includes coating layer 102A between wafer 101A and coating layer 103A.

Referring to FIG. 1A, in one embodiment, exemplified by solar cell 100A, the coating layer 103A can be formed on the surface of the wafer 101A. In one embodiment, the high refractive index coating layer 105A can be formed on the coating layer 103A. And, the coating layer 107A can be formed on the high refractive index coating layer 105A.

In the embodiment exemplified by solar cell 100A′, the coating layer 102A can be formed on the surface of the wafer 101A, and the coating layer 103A can be formed on the coating layer 102A beneath the high refractive index coating layer 105A.

Referring to FIG. 1A, in one embodiment, the wafer 101A can be formed from silicon. In other embodiments, the wafer 101A can be formed from other materials. In one embodiment, the coating layer 102A (solar cell 100A′) can be formed from SiO₂. In other embodiments, the coating layer 102A can be formed from other materials. In one embodiment, the coating layer 102A can be thermally grown. In other embodiments, the coating layer 102A can be formed by other processes.

In one embodiment, the coating layer 103A can be formed from a single layer of material that includes SiNₓ or SiON. In other embodiments, the coating layer 103A can be formed from a single layer of material that includes materials other than SiNₓ or SiON. In one embodiment, instead of a single layer of SiNₓ or SiON multiple layers of material can be used. For example, in one embodiment, if multiple layers of materials are used, the multiple layers of material can include but are not limited to including respective layers of SiNₓ and SiON. In one embodiment, the coating layer 103A can be formed by plasma enhanced chemical vapor deposition (PECVD). In other embodiments, the coating layer 103A can be formed using other methods.

In one embodiment, the high refractive index coating layer 105A can be formed from TiO₂. In other embodiments, the high refractive index coating layer 105A can be formed from other materials. In one embodiment, the high refractive index coating layer 105A can be formed by PECVD. In other embodiments, the high refractive index coating layer 105A can be formed by other methods.

In one embodiment, the coating layer 107A can be formed from a single layer of material that includes SiNₓ or SiON. In other embodiments, the coating layer 107A can be formed from a single layer of material that includes materials other than SiNₓ or SiON. In one embodiment, instead of a single layer of SiNₓ or SiON, multiple layers of material can be used. For example, in one embodiment, if multiple layers of materials are used, the multiple layers of material can include but are not limited to including respective SiNₓ and SiON layers. In one embodiment, the coating layer 107A can be formed by PECVD. In other embodiments, the coating layer 107A can be formed by other methods.

In the embodiment exemplified by solar cell 100A′, the coating layer 102A can be formed from SiO₂. In other embodiments exemplified by the solar cell 100A′, the coating layer 102A can be formed from other materials.

In one embodiment, the coating layer 103A can have a thickness of 10 nm. In other embodiments, the coating layer 103A can have other thicknesses. In one embodiment, the high refractive index coating layer 105A can have a thickness of 45 to 60 nm. In other embodiments, the high refractive index coating layer 105A can have other thicknesses. In one embodiment, the coating layer 107A can have a thickness of 120 nm. In other embodiments, the coating layer 107A can have other thicknesses.

In the embodiment exemplified by solar cell 100A′ the coating layer 102A can have a thickness of 4 nm. In other embodiments exemplified by solar cell 100A′, the coating layer 102A can have other thicknesses.

In one embodiment, the use of a low-reflection and low-absorption material such as TiO₂ with a higher refractive index than SiNₓ or SiON as part of the front surface anti-reflection coating, where the TiO₂ is positioned in the anti-reflection coating stack relative to layers of either SiNₓ or SiON, or both, as described herein, enables a substantial reduction of light reflection losses. In one embodiment, this is facilitated by structuring the film of the stack of films to have different refractive indices where the refractive indices of the film as well as film thicknesses are set to significantly reduce light reflection.

In one embodiment, the materials used in the anti-reflection coating are chosen and formed in a manner that maximizes light trapping, improves wafer surface passivation, and limits light absorption losses. In one embodiment, factors that can be managed to control the final condition of the anti-reflection coating include but are not limited to the stoichiometry of the materials used in the anti-reflection coating and the impurities in the materials used in the anti-reflection coating. In one embodiment, processes that can be managed to control the final condition of the anti-reflection coating can include but are not limited to deposition technique, flow rates of precursors, deposition pressure, and plasma power density.

### Front Surface Anti-Reflection Coating Structure

FIG. 1B shows front surface anti-reflection coating configurations for solar cells 100B and 100B′ with an improved front surface anti-reflection coating according to one embodiment. In one embodiment, the solar cell 100B includes a Si wafer 101B that is covered by a multilayered anti-reflection coating that includes SiNₓ-coating layer 103B, TiO₂-high refractive index coating layer 105B, and SiNₓ-coating layer 107B. In one embodiment, as exemplified by the solar cell 100B′, the Si wafer 101B can be covered by an anti-reflection coating that includes coating layer 102B that is formed on the Si wafer 101B underneath the SiNₓ-coating layer 103B.

Referring to FIG. 1B, in the embodiment exemplified by the solar cell 100B, the SiNₓ-coating layer 103B provides passivation of the surface of the wafer 101B. In one embodiment, the SiNₓ-coating layer 103B can be deposited. In one embodiment, the SiNₓ-coating layer 103B can be formed to have a thickness that maximizes passivation effects and minimizes impact on optics. In one embodiment, the SiNₓ-coating layer 103B can be deposited to have a thickness of 10 nm. In other embodiments, the SiNₓ-coating layer 103B can be deposited to have other thicknesses.

In one embodiment, the TiO₂-high refractive index coating layer 105B enhances the anti-reflection function and reduces the level of absorption of the anti-reflection coating. In particular, the TiO₂-high refractive index coating layer 105B helps to minimize the reflection and absorption losses of the anti-reflection coating. In one embodiment, the TiO₂-high refractive index coating layer 105B is positioned such that its charge is spatially removed from the wafer 101B interface. This positioning of the TiO₂-high refractive index coating layer 105B eliminates or reduces any effect of this charge on carriers at the surface of the wafer 101B. In one embodiment, because the materials used in the multilayer anti-reflection coating may have adjustable optical properties, the optical properties of each of the materials in the multilayer anti-reflection coating can be set such that the desirable optical properties of anti-reflection coating are maximized and a multilayered anti-reflection coating that minimizes reflection and absorption losses of incident light is provided. In particular, the optical properties of TiO₂ in combination with those of the other materials in the anti-reflection coating make the anti-reflection coating an effective reducer of light reflection losses.

In one embodiment, the SiNₓ-coating layer 107B enhances the anti-reflection and passivation functions of the anti-reflection coating. In particular, as regards reflection losses, the SiNₓ-coating layer 107B functions as an effective reducer of the reflection of incident light. As regards passivation, the SiNₓ-coating layer 107B, contributes to the passivation of dangling bonds at the surface of wafer 101B by releasing hydrogen during the thermal processes that can be a part of the fabrication of the solar cell 100B. In one embodiment, as part of the fabrication of solar cell 100B, SiNₓ can be deposited on the TiO₂-high refractive index coating layer 105B and then heated in a thermal process. This causes hydrogen atoms to diffuse downward to the surface of wafer 101B where they passivate the dangling bonds at the wafer surface. In this manner, the dangling bonds are rendered inert such that they are no longer electrically active and recombination at the wafer surface is less likely to occur. Surface passivation is important because surface regions of the solar cell can be the site of particularly high recombination.

Referring again to FIG. 1B, in the embodiment exemplified by solar cell 100B′ the SiO₂-coating layer 102B is formed on the wafer 101B and provides passivation of the front surface of the wafer 101B. In addition, in one embodiment, the SiO₂-coating layer 102B operates to retard ultra-violet (UV) light induced degradation. In this manner, in one embodiment, the SiO₂-coating layer 102B can contribute to solar cell longevity. In one embodiment, the SiO₂-coating layer 102B can be formed to have a thickness that maximizes its surface passivation and UV light degradation retarding functionality. In one embodiment, the SiO₂-coating layer 102B can be formed to have a thickness of 4 nm. In other embodiments, the SiO₂-coating layer 102B can have other thicknesses. In one embodiment, the SiO₂-coating layer 102B can be thermally grown.

FIG. 1C shows a front surface anti-reflection coating configuration used in a solar cell 100C and a solar cell 100C′ according to one embodiment. In one embodiment, the solar cell 100C includes a wafer 101C and a multilayered anti-reflection coating that includes SiNₓ-coating layer 103C, TiO₂-high refractive index coating layer 105C, and SiON-coating layer 107C. Referring to FIG. 1C, the front surface anti-reflection coating configuration used in the solar cell 100C is similar to the front surface anti-reflection coating configuration used in the solar cell 100B but includes a top layer, SiON-coating layer 107C, that is formed from SiON instead of SiNₓ.

In one embodiment as shown in FIG. 1C and exemplified by solar cell 100C′, a front surface coating configuration can be provided that is similar to that of the solar cell 100C, that includes SiO₂-coating layer 102C on the wafer 101C underneath the SiNₓ-coating layer 103C.

Referring again to FIG. 1C, in the embodiment exemplified by solar cell 100C′ the SiO₂-coating layer 102C is formed on the wafer 101C and provides passivation of the front surface of the wafer 101C. In addition, in one embodiment, the SiO₂-coating layer 102C operates to retard ultra-violet (UV) light induced degradation. In this manner, in one embodiment, the SiO₂-coating layer 102C contributes to solar cell longevity. In one embodiment, the SiO₂-coating layer 102C is formed to have a thickness that maximizes its surface passivation and UV light degradation retarding functionality. In one embodiment, the SiO₂-coating layer 102C is formed to have a thickness of 4 nm. In other embodiments, the SiO₂-coating layer 102C can have other thicknesses. In one embodiment, the SiO₂-coating layer 102C is thermally grown.

FIG. 1D shows a front surface anti-reflection coating configuration used in a solar cell 100D and a solar cell 100D′ according to one embodiment. In one embodiment, the solar cell 100D includes a wafer 101D and a multilayered anti-reflection coating that includes SiNₓ-coating layer 103D, TiO₂-high refractive index coating layer 105D, SiNₓ coating layer 107D and SiON coating layer 109D.

Referring to FIG. 1D, the front surface anti-reflection coating configuration used in the solar cell 100D is similar to the front surface anti-reflection coating configuration used in the solar cell 100B and the front surface anti-reflection coating configuration used in the solar cell 100C except that it includes a top layer stack that includes both the SiNₓ coating layer 107D and the SiON coating layer 109D, instead of a single coating layer that is formed from either SiNₓ or SiON.

In one embodiment as shown in FIG. 1D and exemplified by the solar cell 100D′ a front surface coating configuration can be provided that is similar to that of the solar cell 100D, that includes SiO₂-coating layer 102D on the wafer 101C underneath the SiNₓ-coating layer 103C.

Referring again to FIG. 1D, in the embodiment exemplified by solar cell 100D′ the SiO₂-coating layer 102D is formed on the front surface of wafer 101D and provides passivation of the front surface of the wafer 101D. In addition, in one embodiment, the SiO₂-coating layer 102D operates to retard ultra-violet (UV) light induced degradation. In this manner, in one embodiment, the SiO₂-coating layer 102D can contribute to solar cell longevity. In one embodiment, the SiO₂-coating layer 102D is formed to have a thickness that maximizes its surface passivation and UV light degradation retarding functionality. In one embodiment, the SiO₂-coating layer 102D is formed to have a thickness of 4 nm. In other embodiments, the SiO₂-coating layer 102D can have other thicknesses. In one embodiment, the SiO₂-coating layer 102D is thermally grown.

In one embodiment, the lower layers of the anti-reflection coating can have a material makeup that is similar to the material makeup of the top layers. For example, the material makeup of the lower layer or layers may not only include SiNₓ (with or without SiO₂ formed on the front surface of the silicon wafer) but can also include but is not limited to including a single SiON layer or a dual layer that includes both SiNₓ and SiON. FIGS. 1E-1J show anti-reflection coating configurations with lower coating layers that include a single SiON coating layer or both SiNₓ and SiON coating layers according to one embodiment. FIG. 1E shows an anti-reflection coating configuration that uses SiON coating layer 103E as a lower layer and SiNₓ coating layer 107E as the top layer. FIG. 1F shows an anti-reflection coating configuration that uses SiON coating layer 103F as a lower layer and SiON coating layer 107F as the top layer. FIG. 1G shows an anti-reflection coating configuration that uses SiON coating layer 103G as a lower layer and SiNₓ coating layer 107G and SiON coating layer 109G as top layers. FIG. 1H shows an anti-reflection coating configuration that uses SiNₓ coating layer 103H and SiON coating layer 104H as lower layers and SiNₓ coating layer 107H as the top layer. FIG. 1I shows an anti-reflection coating configuration that uses SiNₓ coating layer 103I and SiON coating layer 104I as lower layers and SiON coating layer 107I as the top layer. FIG. 1J shows an anti-reflection coating configuration that uses SiNₓ coating layer 103J and SiON coating layer 104J as lower layers and SiNₓ coating layer 107J and SiON coating layer 109J as top coating layers. It should be appreciated that the films SiNₓ, SiON, and SiO₂ shown as a part of the front surface anti-reflection coating configurations of FIGS. 1B-1J are exemplary, however, according to one embodiment, other materials can be used as a part of a front surface anti-reflection coating configuration as well.

### Operation

Referring to FIG. 1K, in operation, light 115K from a light source contacts the front surface of the solar cell 100K which is covered with an anti-reflection coating that includes SiNₓ-coating layer 103K, TiO₂ high refractive index coating layer 105K, and SiNₓ-coating layer 107K. The layers of the anti-reflection coating are designed to have different indexes of refraction to minimize reflection losses. The minimization of reflection losses is enhanced by the presence of the high refractive index coating layer-TiO₂ 105K. The high refractive index coating layer-TiO₂ 105K also operates to reduce the absorption of light by the anti-reflection coating. Thus, as the light travels from the surface of the anti-reflection coating to the surface of the wafer 101K, reflection and absorption losses are minimized. The condition of the wafer surface is largely due to the passivation provided by the SiNₓ-coating layer 103K, in addition to the passivation provided by the SiNₓ-coating layer 107K that is based on a diffusion of hydrogen from the SiNₓ coating layer 107K. Thus, the anti-reflection coating is designed to transmit light with minimized front surface reflection losses to a wafer surface that is conditioned to minimize recombination. This causes a generation of electron-hole pairs that otherwise would not be generated, such as from the additional light, that is not reflected from the front surface, or that is absorbed in the solar cell. In one embodiment, the reduction in optical losses increases the efficiency of the solar cell 100K such that more power can be supplied to loads 117K.

In the FIG. 1K embodiment, contacts 109K, 111K and 113K are shown as located on the backside surface of the solar cell 100K. However, in one embodiment, contacts such as these can be formed on the frontside and the backside of the solar cell 100K. Moreover, although the contacts 109K, 111K and 113K are shown as being formed on the backside surface of the substrate 101K, in one embodiment, the contacts 109K, 111K and 113K can be formed in the surface of the substrate 101K. Referring again to FIG. 1K, it should be appreciated that the operation of solar cell 100K is the same as the operation of solar cell embodiments that use SiO₂ on the surface of wafer.

Method of Forming Solar Cell with Anti-Reflection Coating

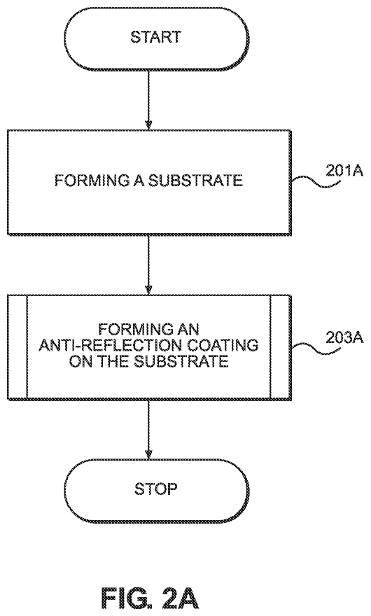

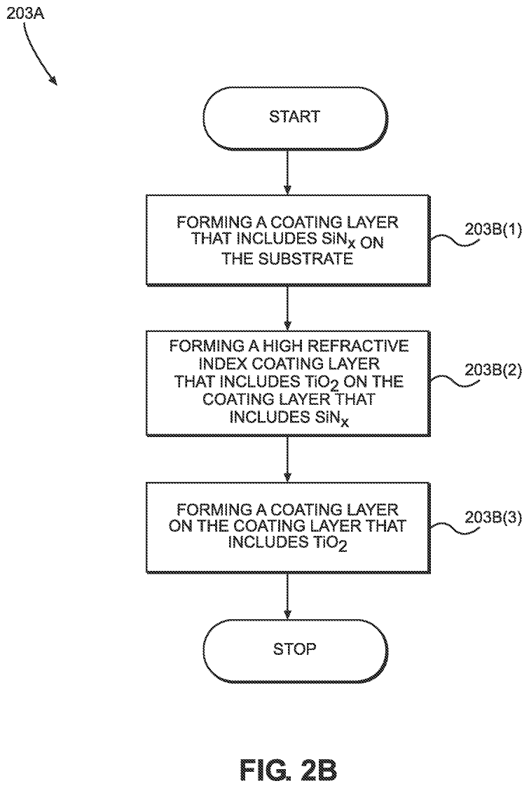

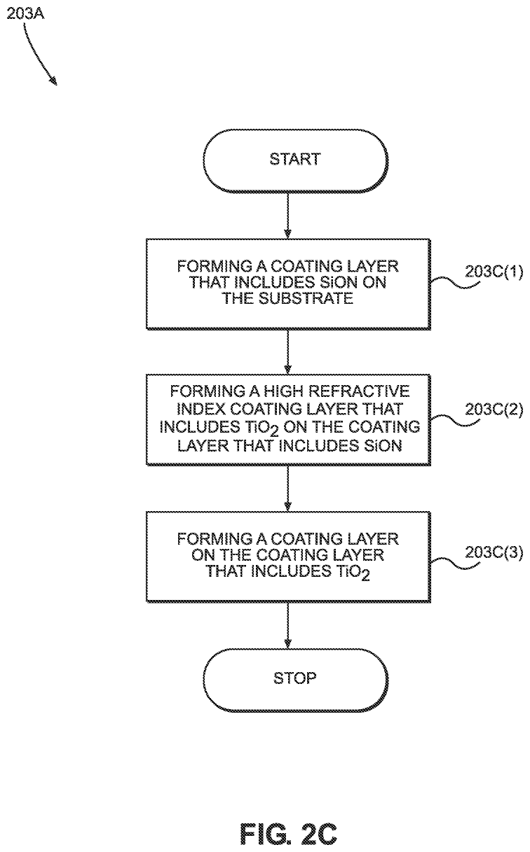

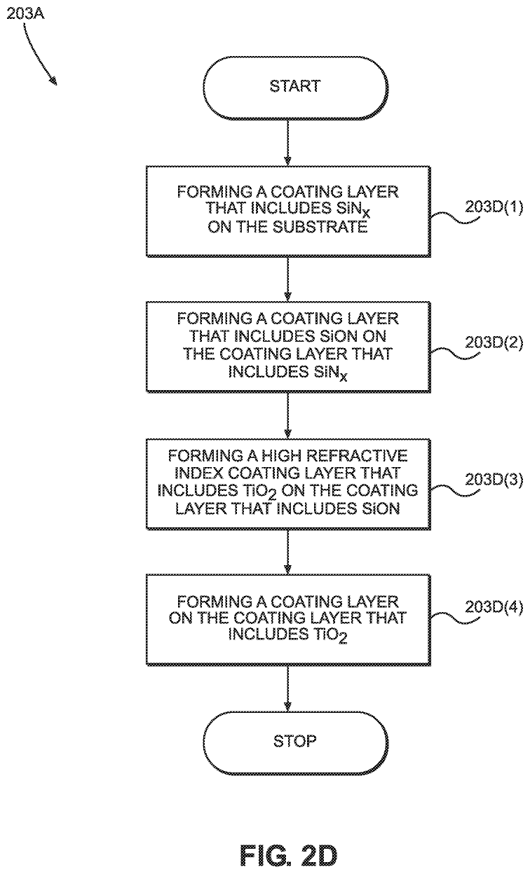

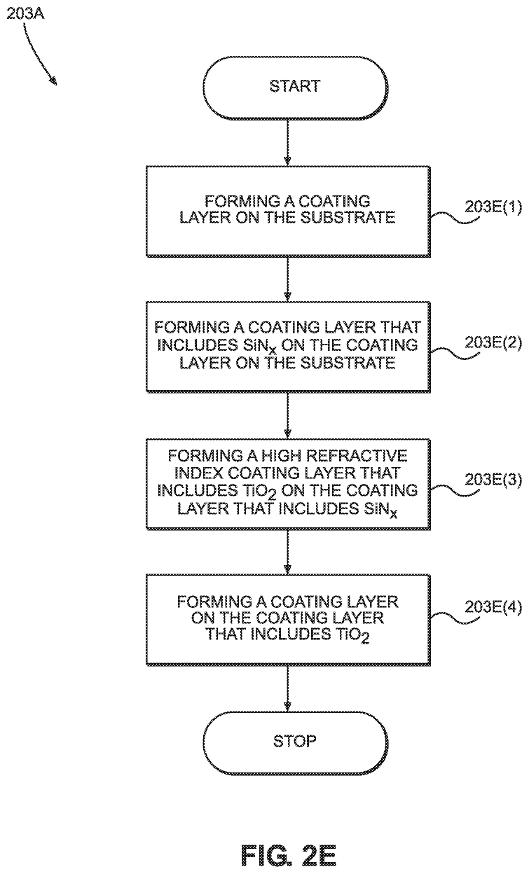

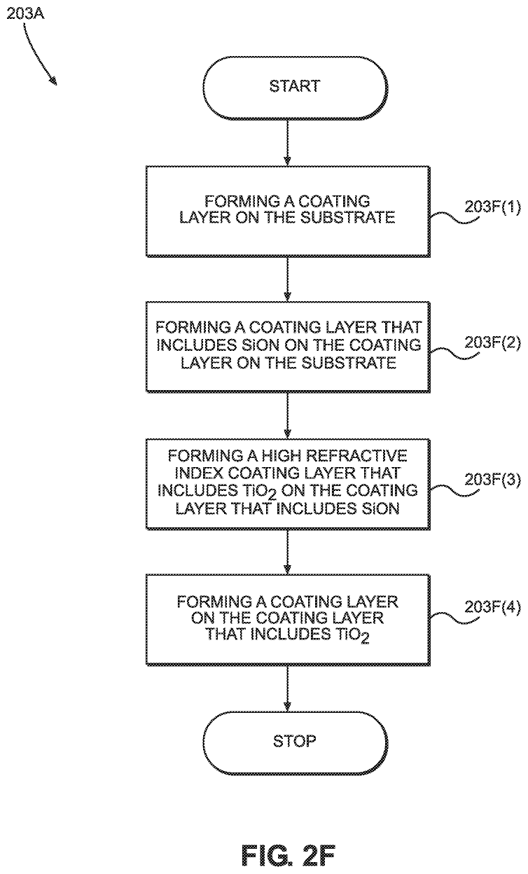

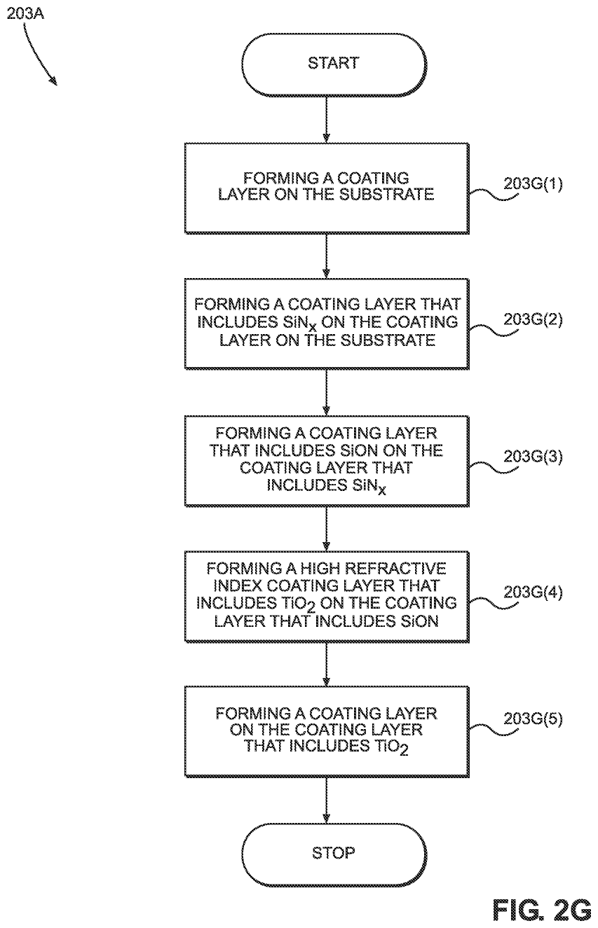

FIG. 2A shows a flowchart of a method of forming a solar cell with an improved anti-reflection coating according to one embodiment. It should be noted that, in one embodiment, the blocks of the flowchart of FIG. 2A are exemplary. FIGS. 2B-2G show flowcharts of respective methods of forming an anti-reflection coating on a substrate (respective methods of executing block 203A of the flowchart shown in FIG. 2A).

Referring to FIG. 2A, the method includes at 201A, forming a substrate, and at 203A, forming an anti-reflection coating on the substrate. FIG. 2B shows a method of forming the anti-reflection coating on the substrate (e.g., 203A) according to one embodiment. Referring to FIG. 2B, the method of forming the anti-reflection coating on the substrate includes, at 203B (1), forming a coating layer that includes SiNₓ on the substrate. At 203B (2), forming an high refractive index coating layer that includes TiO₂ on the coating layer that includes SiNₓ. And, at 203B (3), forming a coating layer on the coating layer that includes TiO₂. Referring to FIG. 2B, in one embodiment, the coating layer on the coating layer that includes TiO₂ can include SiNₓ. Referring again to FIG. 2B, in one embodiment, the coating layer on the coating layer that includes TiO₂ can include SiON. In one embodiment, the method can include forming a coating layer that includes SiON on the coating layer (e.g., if SiNₓ) that is on the coating layer that includes TiO₂.

FIG. 2C shows a method of forming the anti-reflection coating layer on the substrate according to one embodiment. Referring to FIG. 2C, the method of forming the anti-reflection coating layer on the substrate includes, at 203C(1), forming a coating layer that includes SiON on the substrate. At 203C(2), forming a high refractive index coating layer that includes TiO₂ on the coating layer that includes SiON. And at 203C(3), forming a coating layer on the coating layer that includes TiO₂ (the high refractive index coating layer). Referring to FIG. 2C, in one embodiment, the coating layer on the high refractive index coating layer can include SiNₓ. In one embodiment, the coating layer on the high refractive index coating layer can include SiON. In one embodiment, the method can include forming a coating layer on the coating layer that is formed on the high refractive index coating layer (e.g., if SiNₓ) that includes SiON.

FIG. 2D shows a method of forming the anti-reflection coating layer on the substrate according to one embodiment. Referring to FIG. 2D, the method of forming the anti-reflection coating layer on the substrate includes, at 203D(1), forming a coating layer that includes SiNₓ on the substrate. At 203D(2), forming a coating layer that includes SiON on the coating layer that includes SiNₓ. At 203D(3), forming a high refractive index coating layer that includes TiO₂ on the coating layer that includes SiON. And, at 203D(4) forming a coating layer on the coating layer that includes TiO₂. Referring to FIG. 2D, in one embodiment, the coating layer on the high refractive index coating layer can include SiNₓ. In one embodiment, the coating layer on the high refractive index coating layer can include SiON. In one embodiment, the method can include forming a coating layer that includes SiON on the coating layer (e.g., if SiNₓ) that is formed on the high refractive index coating layer.

FIG. 2E shows a method of forming an anti-reflection coating on a substrate according to one embodiment. Referring to FIG. 2E, the method of forming the anti-reflection coating on the substrate includes, at 203E(1), forming a coating layer on the substrate. At 203E(2), forming a coating layer that includes SiNₓ on the coating layer on the substrate. At 203E(3), forming a high refractive index coating layer that includes TiO₂ on the coating layer that includes SiNₓ that is on the coating layer on the substrate. And, at 203E(4), forming a coating layer on the coating layer that includes TiO₂ (the high refractive index coating layer). Referring to FIG. 2E, in one embodiment, the coating layer on the substrate can include SiO₂ and the coating layer on the coating layer that includes TiO₂ can include SiNₓ. Referring again to FIG. 2E, in one embodiment, the coating layer on the coating layer that includes TiO₂ can include SiON. In one embodiment, the method can include forming a coating layer that includes SiON on the coating layer that is on the coating layer includes TiO₂ (e.g., if SiNₓ).

FIG. 2F shows a method of forming the anti-reflection coating layer on the substrate according to one embodiment. Referring to FIG. 2F, the method of forming the anti-reflection coating layer on the substrate includes, at 203F(1), forming a coating layer on the substrate. At 203F(2), forming a coating layer that includes SiON on the coating layer that is on the substrate. At 203F(3), forming a high refractive index coating layer that includes TiO₂ on the coating layer that includes SiON. And at 203F(4), forming a coating layer on the coating layer that includes TiO₂. Referring to FIG. 2F, in one embodiment, the coating layer on the substrate can include SiO₂ and the coating layer on the coating layer that includes TiO₂ can include SiNₓ. In one embodiment, the coating layer on the coating layer that includes TiO₂ can include SiON. In one embodiment, the method can include forming a coating layer that includes SiON on the coating layer that is on the coating layer that includes TiO₂ (e.g., if SiNₓ).

FIG. 2G shows a method of forming the anti-reflection coating layer on the substrate according to one embodiment. Referring to FIG. 2G, the method of forming the anti-reflection coating layer on the substrate includes, at 203G(1), forming a coating layer on the substrate. At 203G(2), forming a coating layer that includes SiNₓ on the coating layer on the substrate. At 203G(3), forming a coating layer that includes SiON on the coating layer that includes SiNₓ. At 203G(4), forming a high refractive index coating layer that includes TiO₂ on the coating layer that includes SiON. And, at 203G(5) forming a coating layer on the coating layer that includes TiO₂. Referring to FIG. 2G, in one embodiment, the coating layer on the substrate can include SiO₂ and the coating layer on the coating layer that includes TiO₂ can include SiNₓ. In one embodiment, the coating layer on the coating layer that includes TiO₂ can include SiON. In one embodiment, the method can include forming a coating layer that includes SiON on the coating layer on the coating layer that includes TiO₂ (e.g., if SiNₓ).

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure. The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The various features of the different embodiments may be variously combined with some features included and others excluded to suit a variety of different applications.

What is claimed is:

1. A method of forming a solar cell, comprising:
forming a substrate; and
forming an anti-reflection coating on the substrate, wherein forming the anti-reflection coating comprises:
forming a coating layer that includes SiNₓ on the substrate;
forming a high refractive index coating layer that includes TiO₂ on the coating layer that includes SiNₓ; and
forming a coating layer on the coating layer that includes TiO₂.

2. The method of forming a solar cell of claim 1, wherein the coating layer on the coating layer that includes TiO₂ includes SiNₓ.

3. The method of forming a solar cell of claim 2, wherein the coating layer on the coating layer that includes TiO₂ includes SiON.

4. The method of forming a solar cell of claim 2, further comprising forming a coating layer that includes SiON on the coating layer that includes SiNₓ that is on the coating layer that includes TiO₂.

5. A method of forming a solar cell, comprising:
forming a substrate; and
forming an anti-reflection coating on the substrate, the anti-reflection coating comprising:
forming a coating layer that includes SiON on the substrate;
forming a high refractive index coating layer that includes TiO₂ on the coating layer that includes SiON; and
forming a coating layer on the coating layer that includes TiO₂.

6. The method of forming a solar cell of claim 5, wherein the coating layer on the coating layer that includes TiO₂ includes SiNₓ.

7. The method of forming a solar cell of claim 5, wherein the coating layer on the coating layer that includes TiO₂ includes SiON.

8. The method of forming a solar cell of claim 6, further comprising forming a coating layer that includes SiON on the coating layer that includes SiNₓ that is on the coating layer that includes TiO₂.

9. A method of forming a solar cell, comprising:
forming a substrate; and
forming an anti-reflection coating on the substrate, the anti-reflection coating comprising:
forming a coating layer that includes SiNₓ on the substrate;
forming a coating layer that includes SiON on the coating layer that includes SiNₓ;
forming a high refractive index coating layer that includes TiO₂ on the coating layer that that includes SiON; and
forming a coating layer on the coating layer that includes TiO₂.

10. The method of forming a solar cell of claim 9, wherein the coating layer on the coating layer that includes TiO₂ includes SiNₓ.

11. The method of forming a solar cell of claim 9, wherein the coating layer on the coating layer that includes TiO₂ includes SiON.

12. The method of forming a solar cell of claim 10, further comprising forming a coating layer that includes SiON on the coating layer that includes SiNₓ that is on the coating layer that includes TiO₂.

13. A method of forming solar cell, comprising:
forming a substrate; and
forming an anti-reflection coating on the substrate, the anti-reflection coating comprising:
forming a coating layer on the substrate;
forming a coating layer that includes SiNₓ on the coating layer on the substrate;
forming a high refractive index coating layer that includes TiO₂ on the coating layer that includes SiNₓ; and
forming a coating layer on the coating layer that includes TiO₂.

14. The method of forming a solar cell of claim 13, wherein the coating layer on the substrate includes SiO₂.

15. The method of forming a solar cell of claim 13, wherein the coating layer on the coating layer that includes TiO₂ includes SiNₓ.

16. The method of forming a solar cell of claim 13, wherein the coating layer on the coating layer that includes TiO₂ includes SiON.

17. The method of forming a solar cell of claim 15, further comprising forming a coating layer that includes SiON on the coating layer that includes SiNₓ that is on the coating layer that includes TiO₂.

18. A method of forming a solar cell, comprising:
forming a substrate; and
forming an anti-reflection coating on the substrate, the anti-reflection coating comprising:
forming a coating layer on the substrate;
forming a coating layer that includes SiON on the coating layer on the substrate;
forming a high refractive index coating layer that includes TiO₂ on the coating layer that includes SiON; and
forming a coating layer on the coating layer that includes TiO₂.

19. The method of forming a solar cell of claim 18, wherein the coating layer on the substrate includes SiO₂.

20. The method of forming a solar cell of claim 18, wherein the coating layer on the coating layer that includes TiO₂ includes SiNₓ.

21. The method of forming a solar cell of claim 18, wherein the coating layer on the coating layer that includes TiO₂ includes SiON.

22. The method of forming a solar cell of claim 20, further comprising forming a coating layer that includes SiON on the coating layer that includes SiNₓ that is on the coating layer that includes TiO₂.

23. A method of forming a solar cell, comprising:
forming a substrate; and
forming an anti-reflection coating on the substrate, the anti-reflection coating comprising:
forming a coating layer on the substrate;
forming a coating layer that includes SiNₓ on the coating layer on the substrate;
forming a coating layer that includes SiON on the coating layer that includes SiNₓ;
forming a high refractive index coating layer that includes TiO₂ on the coating layer that includes SiON; and
forming a coating layer on the coating layer that includes TiO₂.

24. The method of forming a solar cell of claim 23, wherein the coating layer on the substrate includes SiO₂.

25. The method of forming a solar cell of claim 23, wherein the coating layer on the coating layer that includes TiO₂ includes SiNₓ.

26. The method of forming a solar cell of claim 23, wherein the coating layer on the coating layer that includes TiO₂ includes SiON.

27. The method of forming a solar cell of claim 25, further comprising forming a coating layer that includes SiON on the coating layer that includes SiNₓ that is on the coating layer that includes TiO₂.
